(19) United States
(12) Patent Application Publication
(10) Pub. No.: US 2019/0326368 A1
(43) Pub. Date: Oct. 24, 2019

(54) OLED COMPONENT, METHOD FOR MANUFACTURING THE SAME AND OLED DISPLAY

(71) Applicant: Shenzhen China Star Optoelectronics Semiconductor Display Technology Co., Ltd., Shenzhen (CN)

(72) Inventors: Yingchun Fan, Shenzhen (CN); Xiaoxing Zhang, Shenzhen (CN)

(21) Appl. No.: 16/041,849

(22) Filed: Jul. 23, 2018

Related U.S. Application Data
(63) Continuation of application No. PCT/CN2018/092070, filed on Jun. 21, 2018.

(30) Foreign Application Priority Data
Apr. 23, 2018 (CN) 201810367806.2

(51) Int. Cl. H01L 27/32; H01L 51/56; H01L 51/50; H01L 51/52

(52) U.S. Cl. CPC H01L 27/3246; H01L 27/3258; H01L 27/3262; H01L 51/5221; H01L 51/5012; H01L 51/5206; H01L 51/56

(57) ABSTRACT

The present disclosure provides an OLED component, a method for manufacturing the same and an OLED display. The OLED component includes a baseplate; a pixel define layer, an insulation layer and an organic light-emitting unit successively disposed on the baseplate; wherein the pixel define layer defines a light-emitting area, the organic light-emitting unit is located in the light-emitting area, and the insulation layer is arranged between the pixel define layer and the organic light-emitting unit. Therefore, the implementation of the present disclosure may prevent impurities in the pixel define layer from entering into the organic light-emitting unit.

### CROSS-REFERENCE TO RELATED APPLICATIONS

The present application is a continuation-application of International (PCT) Patent Application No. PCT/CN2018/092070, field on Jun. 21, 2018, which claims foreign priority of Chinese Patent Application No. 201810367806.2, field on Apr. 23, 2018 in the State Intellectual Property Office of China, the entire contents of which are hereby incorporated by reference.

### TECHNICAL FIELD

The present disclosure generally relates to the display technique field, and in particular to an organic light-emitting diode (OLED) component, a method for manufacturing the same and an OLED display.

### BACKGROUND

Compared with traditional LCD displays, the OLED display panel can provide fast response, high contrast and wide field of view, and is considered as the next generation display technology. As shown in FIG. 1, an OLED component 10 may generally include a thin film transistor (TFT) baseplate 11. It may further include a planarization (PLN) layer 12, a pixel define layer (PDL) 13, and an organic light-emitting unit 14 disposed on the TFT baseplate 11. The OLED component 10 may also include a cover glass 151 and a dam 152 as enclosure.

The working principle of the OLED component can be explained as follows in reference to FIG. 1. When a voltage is applied across the anode 141 and the cathode 142 of the organic light-emitting unit 14, electrons and holes driven by the voltage move respectively from the cathode 142 and the anode 141 to the electron transmission layer and the hole transmission layer, and then to the light-emitting layer 143. The electrons and the holes meet at the light-emitting layer 143 to form the exciton and emit visible light. The light-emitting unit 14 is very sensitive to impurities such as moisture and oxygen. Since the organic light-emitting unit 14 is disposed next to the pixel define layer 13, impurities such as moisture and oxygen in the pixel define layer 13 may probably enter into the organic light-emitting unit 14. In this condition, the photoelectric performance of the organic light-emitting unit 14 will be reduced, as well as the service life of the OLED component 10.

### SUMMARY

Accordingly, the present disclosure provides an OLED component, a method for manufacturing the same and an OLED display so as to prevent impurities in the pixel define layer from entering into the organic light-emitting unit.

The present disclosure provides an OLED component. The OLED component includes a baseplate; a pixel define layer, an insulation layer and an organic light-emitting unit successively disposed on the baseplate; wherein the pixel define layer defines a light-emitting area, the organic light-emitting unit is located in the light-emitting area, and the insulation layer is arranged between the pixel define layer and the organic light-emitting unit.

The present disclosure provides an OLED display with an OLED component. The OLED component includes a baseplate; a pixel define layer, an insulation layer and an organic light-emitting unit successively disposed on the baseplate; wherein the pixel define layer defines a light-emitting area, the organic light-emitting unit is located in the light-emitting area, and the insulation layer is arranged between the pixel define layer and the organic light-emitting unit.

The present disclosure provides a method for manufacturing an OLED component. The method includes: providing a baseplate; forming an anode of an organic light-emitting unit on the baseplate; forming a pixel define layer on the baseplate; forming an insulation layer on the pixel define layer; forming a rest of the organic light-emitting unit in a light-emitting area defined by the pixel define layer, wherein the rest of the organic light-emitting unit comprises a light-emitting layer and a cathode, and the insulation layer is located between the pixel define layer and the organic light-emitting unit.

By disposing an insulation layer between the pixel define layer and the organic light-emitting unit, the present disclosure may prevent impurities in the pixel define layer from entering into the organic light-emitting unit.

### BRIEF DESCRIPTION OF THE DRAWINGS

FIG. 1 is a schematic diagram of an OLED component according to related art.

FIG. 2 shows a schematic diagram of an OLED component according to an embodiment of the present disclosure.

FIG. 3 shows a schematic diagram of the OLED component of FIG. 2 with a bottom type thin film transistor.

FIG. 4 is a flow chart of a manufacturing method for an OLED component according to an embodiment of the present disclosure.

FIG. 5 shows the process of the method for manufacturing the OLED component of FIG. 4.

### DETAILED DESCRIPTION

The purpose of the present disclosure is to provide, for a display with OLED component, an insulation layer between the pixel define layer and the organic light-emitting unit. The insulation layer is utilized to prevent impurities such as moisture and oxygen from entering into the organic light-emitting unit. Thus, the implementation of the present disclosure may prevent impurities in the pixel define layer from entering into the organic light-emitting unit so as to improve the photoelectric performance of the organic light-emitting unit and the service life of the OLED component.

The disclosure will now be described in detail with reference to the accompanying drawings and examples. The following embodiments and the features in the embodiments can be combined with each other as long as no conflict is caused. Moreover, the directional terms used in the entire application, such as “up” and “down”, are all for better describing the technical solutions of various embodiments, and are not intended to limit the protection scope of the present application.

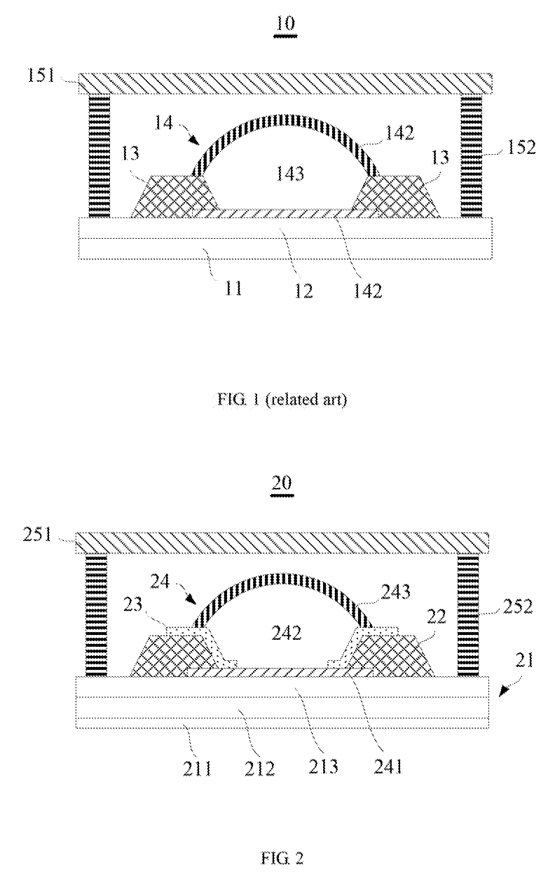

FIG. 2 shows a schematic diagram of an OLED component according to an embodiment of the present disclosure. As shown in FIG. 2, the OLED component 20 may include a baseplate 21, a pixel define layer 22, an insulation layer 23, an organic light-emitting unit 24, a cover glass 251 and a dam 252. The pixel define layer 22, the insulation layer 23 and the organic light-emitting unit 24 may be successively disposed on the baseplate 21. The cover glass 251 and the dam 252 may be utilized as enclosure.

The pixel define layer 22 may be utilized to define a light-emitting area of the OLED component 20. The insulation layer 23 may be disposed on the pixel define layer 22. The organic light-emitting unit 24 may be located in the light-emitting area. The organic light-emitting unit 24 may be in direct contact with the insulation layer 23 and may not touch the pixel define layer 22. Specifically, the organic light-emitting unit 24 may include an anode 241, a light-emitting layer 242, a cathode 243, an electron transmission layer and a hole transmission layer. The anode 241 may be disposed on the baseplate 21. The light-emitting layer 242, the electron transmission layer and the hole transmission layer may be arranged between the anode 241 and the cathode 243. The light-emitting layer 242 may be in direct contact with the insulation layer 23, and may not touch the pixel define layer 22.

The insulation layer 23 may be made of transparent insulating material which is capable of insulating water and oxygen, such as silicon dioxide (SiO₂), silicon nitride (SiNₓ), indium tin oxide (ITO) etc. The insulation layer 23 may have a single-layer structure or a multi-layer structure.

Since the insulation layer 23 is located between the organic light-emitting unit 24 and the pixel define layer 22, the insulation layer 23 is capable of insulating impurities such moisture and oxygen emitted from the pixel define layer 22. Thus, the present disclosure may prevent impurities such as moisture and oxygen in the pixel define layer 22 from entering into the organic light-emitting unit 24 so as to improve the photoelectric performance of the organic light-emitting unit 24 and service life of the OLED component 20.

In this embodiment, the insulation layer 23 may only cover a portion of the organic light-emitting unit 24 which is next to the organic light-emitting unit 24, i.e., the insulation layer 23 may not cover the whole outer surface of the pixel define layer 22. In other embodiments, for better insulating water and oxygen, the insulation layer 23 may also cover the whole outer surface of the pixel define layer 22.

Referring to FIG. 2, the baseplate 21 may be a TFT baseplate, which includes a substrate 211, a TFT layer 212 and a planarization layer 213. The TFT layer 212 and the planarization layer 213 may be disposed successively on the substrate 211. The above-mentioned pixel define layer 22, the insulation layer 23 and the organic light-emitting unit 24 may all be disposed on the planarization layer 213. The TFT layer 212 may include a gate electrode, a source electrode, a drain electrode and an active layer etc. The planarization layer 213 may define a via hole which exposes the drain electrode of the TFT layer 212. The anode 241 of the organic light-emitting unit 24 may cover the via hole so as to be in contact with the drain electrode of the TFT layer 212.

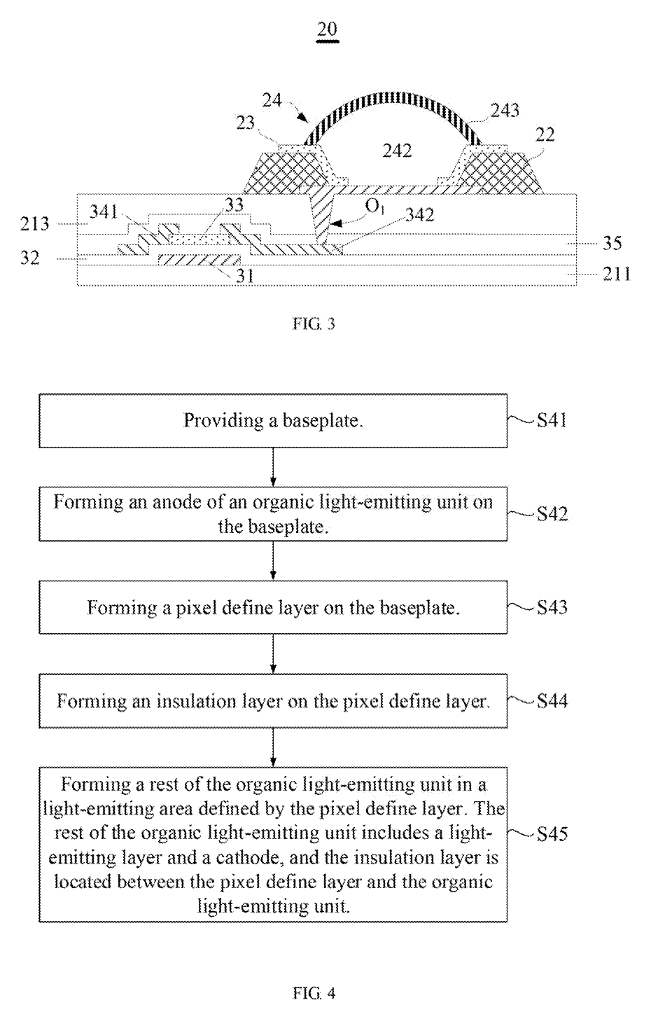

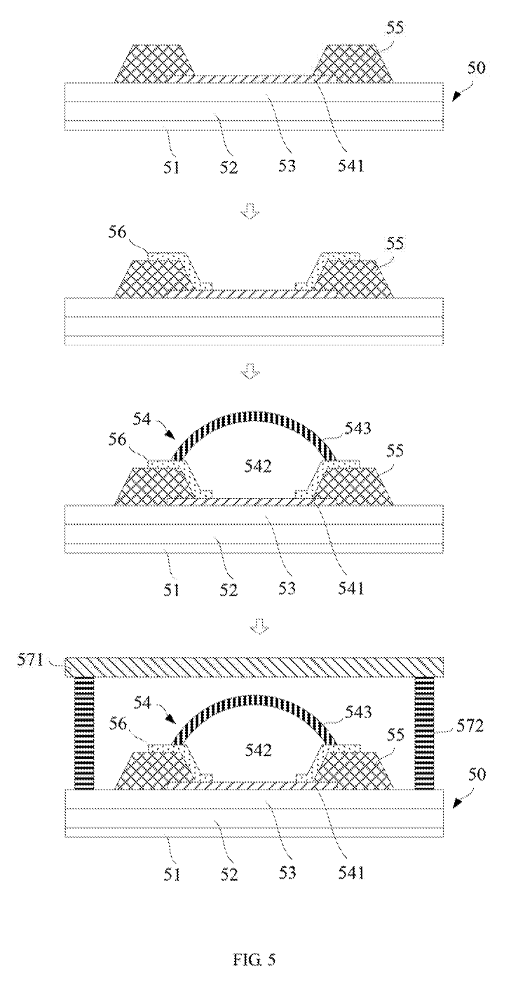

The structure design and material for the thin film transistor in the TFT layer 212 are not limited in the present disclosure. For example, the thin film transistor may be of a bottom gate type or a top gate type. The metal wires or pattern in the TFT may be made of one of or a combination of ITO, molybdenum (MO), aluminum (AL), titanium (Ti), copper (Cu) and so on. The structure of the OLED component 20 will be further described in reference to the TFT structure shown in FIGS. 3 and 4.

FIG. 3 shows a schematic diagram of the OLED component of FIG. 2 with a bottom type thin film transistor. As shown in FIG. 3, the TFT layer 212 may include multiple layers formed successively on the substrate 211, i.e., the gate electrode 31, the gate insulation (GI) layer 32, the active layer 33, a source-drain electrode layer consisting of the source electrode 341 and the drain electrode 342 and a passivation (PV) layer 35.

The gate electrode 31, the gate insulation layer 32, the active layer 33, the source electrode 341, the drain electrode 342 and the passivation layer 35 may constitute the thin film transistor in the TFT layer 212. Given that the gate electrode 31 is located below the active layer 33, the OLED component 20 may be consider to have a bottom gate type thin film transistor.

As shown in FIGS. 2 and 3, the planarization layer 213 may cover the passivation layer 35. The planarization layer 213 and the passivation layer 35 of the TFT cooperatively define a via hole O₁ passing therethrough. The via hole O₁ may expose the upper surface of the drain electrode 342. The anode 241 of the organic light-emitting unit 24 may cover the via hole O₁ so as to be in contact with the drain electrode 342. Therefore, the organic light-emitting unit 24 may be electrically connected to the drain electrode 342 of the TFT.

It should be understood, the TFT layer 212 may alternatively have a top gate type thin film transistor. The design of a top gate type thin film transistor can be found in prior art and will not be described hereon.

FIG. 4 is a flow chart of a manufacturing method for an OLED component according to an embodiment of the present disclosure. FIG. 5 shows the process of the method for manufacturing the OLED component of FIG. 4. As shown in FIGS. 4 and 5, the method for manufacturing the OLED component may include blocks S41˜S45.

S41: Providing a baseplate.

As shown in FIG. 5, the baseplate 50 may be a TFT baseplate, which includes a substrate 51, a TFT layer 52 and a planarization layer 53. The TFT layer 52 and the planarization layer 53 may be disposed successively on the substrate 51. The TFT layer 52 may include a gate electrode, a source electrode, a drain electrode and an active layer etc. The planarization layer 53 may define a via hole which exposes the drain electrode of the TFT layer 52.

The substrate 51 may be a transparent substrate such as glass substrate, plastic substrate and flexible substrate. The structure design and material for the thin film transistor in the TFT layer 52 are not limited in the present disclosure. For example, the thin film transistor may be of a bottom gate type or a top gate type.

For a bottom type TFT layer 52, the process provided by the present disclosure for manufacturing the TFT may include following blocks.

First, a metal layer may be formed on one surface of the substrate 51 by physical vapor deposition (PVD). Then the metal layer may be patterned and only a portion of the metal layer located in a pre-determined region is kept so as to form the gate electrode. The patterning process may include light resistance material coating, exposing, developing, etching etc. Details of the process may be found in prior art and will not be described hereon.

Second, a gate insulation layer completely covering one surface of the gate electrode may be formed by chemical vapor deposition (CVD). The gate insulation layer may be made of oxide of silicon (SiOₓ). Or, the gate insulation layer may alternatively include a layer of oxide of silicon and a layer of silicon nitride successively disposed on the gate electrode, such as a layer of SiO₂ and a layer of Si₃N₄, so as to make the gate insulation layer more durable and to improve its insulating performance.

Then, an active layer may be formed by CVD. The active layer may be patterned such that only a portion of the active layer corresponding to the location of the gate electrode is kept. Alternatively, the active layer may directly be formed and patterned by CVD under a mask with the pre-determined pattern.

At last, the source electrode and the drain electrode can be acquired by the same process as that utilized for manufacturing the gate electrode. Also the passivation layer covering the source electrode and the drain electrode may be formed.

Therefore, the required TFT can be obtained by above-described processes.

The planarization layer 53 may cover a whole surface of the TFT. The planarization layer 53 may be formed by CVD or polyimide (PI) coating. Then the via hole exposing the drain electrode may be formed by etching the planarization layer 53 corresponding to the location of the drain electrode of the TFT.

S42: Forming an anode of an organic light-emitting unit on the baseplate.

As shown in FIG. 5, the anode 541 may be formed by a patterning process including light resistance material coating, exposing, developing and etching. Specifically, one surface of the planarization layer 53 may be coated with a metal layer. Then the metal layer may be coated with light resistance material. The light resistance material may be exposed under a mask such that one pre-determined region of the light resistance material is exposed while the other portion is covered by the mask and not exposed. After developing, the portion of light resistance material exposed may be removed while the other portion which is not exposed may be kept. By etching the metal layer, one portion of the metal layer which is not covered by the rest light resistance material may be removed while the other portion of the metal layer may be kept. Thus the patterned anode 541 can be acquired. The anode 541 may cover the via hole of the planarization layer 53 so as to be in contact with the drain electrode of the TFT.

S43: Forming a pixel define layer on the baseplate.

The pixel define layer 55 may be utilized for defining a light-emitting area of the OLED component. The pixel define layer 55 may cover a portion of the anode 541. The pixel define layer 55 may be formed by a patterning process including light resistance material coating, exposing, developing and etching.

S44: Forming an insulation layer on the pixel define layer.

The insulation layer 56 may only cover a portion of the pixel define layer 55 which is next to the organic light-emitting unit 54, i.e., the insulation layer 56 may only covers a portion of the outer surface of the pixel define layer 55. It should be noticed, for better insulating water and oxygen, the insulation layer 56 may cover the whole outer surface of the pixel define layer 55.

The insulation layer 56 may be formed by CVD or a patterning process including light resistance material coating, exposing, developing and etching. Alternatively, the insulation layer 56 may be deposited on the pixel define layer 55 by evaporation under a mask.

S45: Forming a rest of the organic light-emitting unit in a light-emitting area defined by the pixel define layer. The rest of the organic light-emitting unit may include a light-emitting layer and a cathode, and the insulation layer may be located between the pixel define layer and the organic light-emitting unit.

The light-emitting layer 542 and the cathode 543 may be formed by evaporation or printing according to the present disclosure. Obviously, the organic light-emitting unit 54 may further include other structures, such as electron transmission layer and hole transmission layer. These structures can be acquired according to prior art and thus are not shown in the figures.

Furthermore, the cover glass 571 and the dam 572 may be formed so as to encapsulate the structures formed in blocks S41˜S45. Specifically, the dam 572 may be arranged on the planarization layer 53 and surrounding the organic light-emitting unit 54. The cover glass 571 may be disposed on the dam 572 and corresponding to the location of the planarization layer 53. The cover glass 571, the dam 572 and the baseplate 50 cooperatively define a confined chamber in which the other elements of the OLED components 20 may be disposed.

The OLED component manufactured according to the manufacturing method described in this embodiment may have the same structure as the foregoing OLED component 20. Thus, similar advantageous may be achieved.

The foregoing is merely embodiments of the present disclosure, and is not intended to limit the scope of the disclosure. Any transformation of equivalent structure or equivalent process which uses the specification and the accompanying drawings of the present disclosure, or directly or indirectly application in other related technical fields, are likewise included within the scope of the protection of the present disclosure.

What is claimed is:

1. An OLED component, comprising:
a baseplate;
a pixel define layer, an insulation layer and an organic light-emitting unit successively disposed on the baseplate;
wherein the pixel define layer defines a light-emitting area, the organic light-emitting unit is located in the light-emitting area, and the insulation layer is arranged between the pixel define layer and the organic light-emitting unit.

2. The OLED component of claim 1, wherein
the insulation layer covers a whole outer surface of the pixel define layer; or
the insulation layer covers a portion of the pixel define layer corresponding to a location of the organic light-emitting unit.

3. The OLED component of claim 1, wherein the insulation layer comprises transparent insulating material.

4. The OLED component of claim 3, wherein the insulation layer has a single-layer structure or a multi-layer structure.

5. The OLED component of claim 1, wherein the baseplate comprises:
a substrate;
a TFT layer and a planarization layer successively disposed on the substrate;
wherein the pixel define layer, the insulation layer and the organic light-emitting layer are set on the planarization layer, the planarization layer defines a via hole exposing a drain electrode of the TFT layer, and an anode of the organic light-emitting unit covers the via hole so as to be in contact with the drain electrode.

6. An OLED display with an OLED component, wherein the OLED component comprises:
a baseplate;
a pixel define layer, an insulation layer and an organic light-emitting unit successively disposed on the baseplate;
wherein the pixel define layer defines a light-emitting area, the organic light-emitting unit is located in the light-emitting area, and the insulation layer is arranged between the pixel define layer and the organic light-emitting unit.

7. The OLED display of claim 6, wherein
the insulation layer covers a whole outer surface of the pixel define layer; or
the insulation layer covers a portion of the pixel define layer corresponding to a location of the organic light-emitting unit.

8. The OLED display of claim 6, wherein the insulation layer comprises transparent insulating material.

9. The OLED display of claim 8, wherein the insulation layer has a single-layer structure or a multi-layer structure.

10. The OLED display of claim 6, wherein the baseplate comprises:
a substrate;
a TFT layer and a planarization layer successively disposed on the substrate;
wherein the pixel define layer, the insulation layer and the organic light-emitting layer are set on the planarization layer, the planarization layer defines a via hole exposing a drain electrode of the TFT layer, and an anode of the organic light-emitting unit covers the via hole so as to be in contact with the drain electrode.

11. A method for manufacturing an OLED component, comprising:
providing a baseplate;
forming an anode of an organic light-emitting unit on the baseplate;
forming a pixel define layer on the baseplate;
forming an insulation layer on the pixel define layer; and
forming a rest of the organic light-emitting unit in a light-emitting area defined by, the pixel define layer, wherein the rest of the organic light-emitting unit comprises a light-emitting layer and a cathode, and the insulation layer is located between the define layer and the organic light-emitting unit.

12. The method of claim 11, wherein the forming an insulation layer comprises:
forming the insulation layer by a patterning process including light resistance material coating, exposing, developing and etching; or
depositing the insulation layer on the pixel define layer by evaporation under a mask.

13. The method of claim 11, wherein
the insulation layer covers a whole outer surface of the pixel define layer; or
the insulation layer covers a portion of the pixel define layer corresponding to a location of the organic light-emitting unit.

14. The method of claim 11, wherein the insulation layer comprises transparent insulating material.

15. The method of claim 14, wherein the insulation layer has a single-layer structure or a multi-layer structure.

16. The method of claim 11, wherein the baseplate comprises:
a substrate;
a TFT layer and a planarization layer successively disposed on the substrate;
wherein the pixel define layer, the insulation layer and the organic light-emitting layer are set on the planarization layer, the planarization layer defines a via hole exposing a drain electrode of the TFT layer, and an anode of the organic light-emitting unit covers the via hole so as to be in contact with the drain electrode.
